(19) United States
(12) Patent Application Publication
(10) Pub. No.: US 2024/0107688 A1
(43) Pub. Date: Mar. 28, 2024

(54) METAL ELEMENT OF A PROTECTIVE CASING OF A COMPUTER FOR A MOTOR VEHICLE

(71) Applicant: VITESCO TECHNOLOGIES GMBH, Regensburg (DE)

(72) Inventors: Corentin DELEBARRE, Toulouse (FR); Ludovic LEBLANC, Toulouse (FR)

(21) Appl. No.: 18/263,609

(22) PCT Filed: Mar. 11, 2022
(86) PCT No.: PCT/EP2022/056304

§ 371 Date: Jul. 31, 2023

(30) Foreign Application Priority Data
Mar. 17, 2021 (FR) FR2102667

(51) Int. Cl. H05K 5/00; H05K 5/03; H05K 13/00

(52) U.S. Cl. CPC H05K 5/006; H05K 5/03; H05K 13/0015

(57) ABSTRACT

Disclosed is a metal element, such as a structural support or a cover, of a protective casing of a computer for a motor vehicle, which metal element has a first face, which is intended to be oriented toward the exterior of the protective casing, and a second face, which is intended to be oriented toward the interior of the protective casing, the element including a printed circuit board, characterized in that the element includes at least one deformation that protrudes with respect to the first face, the printed circuit board being attached to the second face by way of a self-tapping screw implanted in the deformation.

### TECHNICAL FIELD OF THE INVENTION

The invention relates to a metal element of a protective casing of a computer for a motor vehicle comprising a printed circuit board.

### PRIOR ART

It is known practice in the prior art for a motor vehicle to comprise one or more computers that have the role of managing various items of equipment installed in the motor vehicle, such as the electronic injection or the power-assisted steering system. A computer, also referred to as an ECU (engine control unit), is arranged in a protective casing comprising a cover and a support structure. In particular, the computer comprises a printed circuit board, which is also referred to as a PCB. The printed circuit board is attached to the sheet metalwork of the protective casing by means of one or more rivets. The rivets are directly obtained by stamping the sheet metalwork. The rivets are then inserted into the perforations in the printed circuit board that are intended to receive them. Finally, the rivets are flattened such that the printed circuit board is attached to the sheet metalwork of the protective casing. The disadvantage of riveting is that there is a risk of cracks appearing at the portion of the rivet that has been flattened. This results in the printed circuit board not being securely attached to the protective casing. Furthermore, chips may be produced during the flattening of the rivets, which may potentially create short circuits within the printed circuit board.

The prior art also discloses an attachment system comprising an insert in which a screw is assembled. The insert is crimped to the protective casing and is thus an add-on component. The insert may also be welded or riveted. The connection between the insert and the protective casing may have defects that result in a lack of sealing between the interior of the protective casing and the external environment thereof. Thus, external elements, such as dust or water, may penetrate into the interior of the protective casing and cause various kinds of damage to the printed circuit board.

The aim of the present invention is therefore to overcome the disadvantages of the prior art by proposing an attachment device that is straightforward to implement, allows the printed circuit board to be fixedly attached to the protective casing, and has enhanced sealing.

### DISCLOSURE OF THE INVENTION

To this end, the invention thus relates, in its broadest sense, to a metal element, such as a structural support or a cover, of a protective casing of a computer for a motor vehicle, which metal element has a first face, which is intended to be oriented toward the exterior of said protective casing, and a second face, which is intended to be oriented toward the interior of said protective casing, said element comprising a printed circuit board, distinguished in that said element comprises at least one deformation that protrudes with respect to said first face, said printed circuit board being attached to said second face by way of a self-tapping screw implanted in said deformation.

Advantageously, said deformation comprises a base, said base being rounded or flat.

According to one advantageous feature, said deformation comprises an opening, said element comprising a planar surface arranged around said opening.

Preferably, said self-tapping screw has a hexagonal socket.

Preferably, said element is made from an alloy of aluminum or a steel, preferably a stainless steel, and said self-tapping screw is made from a steel, preferably a stainless steel.

Preferably, said self-tapping screw has an under-head length and said deformation has a shaft that has a length that is shorter than the under-head length of said self-tapping screw.

Preferably, said element comprises at least three deformations, each comprising a self-tapping screw.

The invention also relates to a protective computer casing for a motor vehicle comprising at least one element as described above.

Another subject of the invention is a method for assembling a metal element of a protective casing of a computer for a motor vehicle, which metal element has a first face, which is intended to be oriented toward the exterior of said protective casing, and a second face, which is intended to be oriented toward the interior of said protective casing, said element comprising a printed circuit board, said method being distinguished in that it comprises the following steps:
a step of producing a deformation in said element that protrudes with respect to said first face;
a step of positioning said printed circuit board on said second face;
a step of screwing a self-tapping screw into said deformation in order to assemble said printed circuit board with said element.

Advantageously, the step of producing said deformation is achieved by stamping.

### BRIEF DESCRIPTION OF THE DRAWINGS

Several embodiments of the present invention will be described hereinbelow by way of nonlimiting examples and with reference to the appended figures, in which:

FIG. 1 schematically shows an isometric view of a support structure, comprising various components, of a protective casing according to a first embodiment of the invention;

FIG. 2 schematically illustrates a sectional view of an attachment means that can be seen in FIG. 1;

FIG. 3 schematically shows an isometric view of a cover, comprising various components, of a protective casing according to a second embodiment of the invention.

### DETAILED DESCRIPTION OF EMBODIMENTS OF THE INVENTION

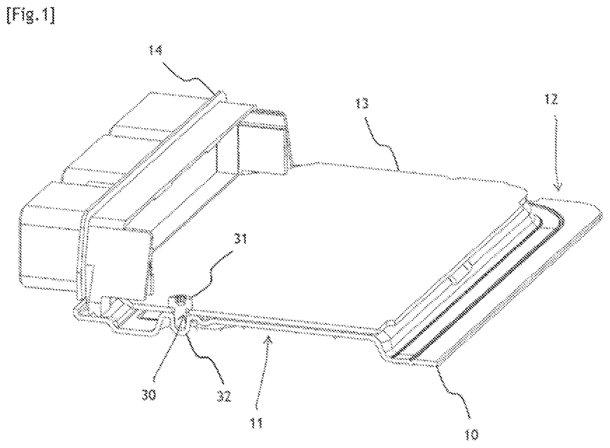

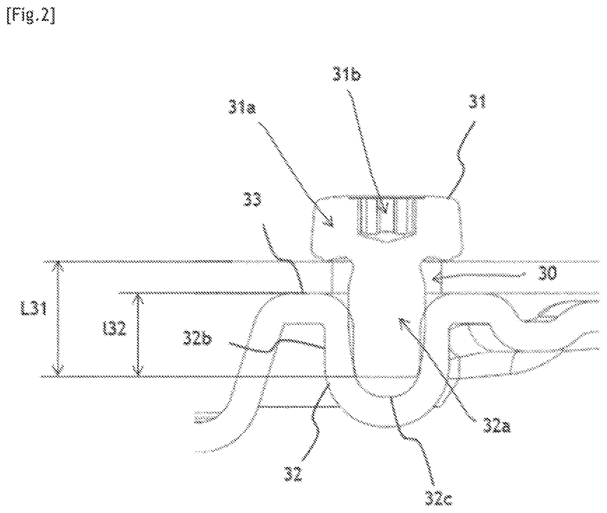

Reference is made to FIG. 1, which schematically shows a structural support 10 of a protective casing for a motor vehicle computer according to a first embodiment of the present invention. The structural support 10 has a first face 11, which is intended to be oriented toward the exterior of the protective casing, and a second face 12, which is intended to be oriented toward the interior of the protective casing. The protective support 10 is made from a metal material, such as an alloy of aluminum or of stainless steel. A printed circuit board 13, which is connected to a set of connectors 14, is attached to the structural support 10. The structural support 10 is intended to be assembled with a cover in order to form a protective casing for a computer. The printed circuit board 13 has an orifice 30, which can be seen more clearly in FIG. 2, through which a self-tapping screw 31 passes. In one alternative, the printed circuit board 13 has a plurality of orifices 30, through which a plurality of self-tapping screws 31 pass, respectively. Furthermore, the structural support 10 comprises a deformation 32 that protrudes with respect to the first face 11. Preferably, the deformation 32 is achieved by stamping since this is a rapid process that is straightforward to implement. The method for assembling the printed circuit board 13 and the structural support 10 comprises a first step of positioning the printed circuit board 13 on the structural support 10, then a second step of inserting the self-tapping screw 31 into the orifice 30, then a third step of tightening the self-tapping screw 31. Thus, the printed circuit board 13 is assembled with the structural support 10. The deformation 32 comprises an opening 32a, a shaft 32b, which has a length 132, and a base 32c. Preferably, the base 32c is rounded. In one alternative, the base 32c is flat. The self-tapping screw 31 has an under-head length L31. The length 132 of the shaft 32b is shorter than the length L31 of the screw 31. It is thereby possible to produce a significant pressing force on the printed circuit board 13. The structural support 10 also comprises a planar surface 33 arranged around the opening 32a. The printed circuit board 13 bears against the planar surface 33. The planar surface 33 and the self-tapping screw 31 thus make it possible to apply pressure to the printed circuit board 13 and to hold it fixedly in place. The self-tapping screw 31 has a head 31a comprising a hexagonal socket 31b. A hexagonal socket 31b has the advantage of being able to receive a relatively large torque, which thus makes it possible to improve the attachment of the printed circuit board 13 to the structural support 10. As an alternative, the head 31a has a cruciform socket or a slot. A protective casing comprising such a structural support 10 has excellent sealing with respect to the external environment. Specifically, the deformation 32 is continuous, which has the advantage of preventing moisture or dust from penetrating into the protective casing.

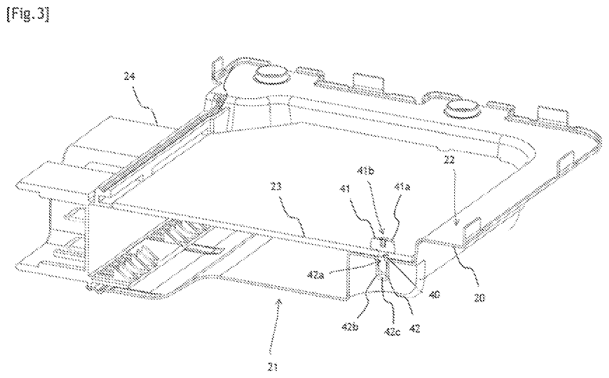

Reference is now made to FIG. 3, which schematically shows a cover 20 of a protective casing for a motor vehicle computer according to a second embodiment of the invention. The cover 20 has a first face 21, which is intended to be oriented toward the exterior of the protective casing, and a second face 22, which is intended to be oriented toward the interior of the protective casing. The cover is made from a metal material, such as an alloy of aluminum or of stainless steel. A printed circuit board 23, which is connected to a set of connectors 24, is attached to the cover 20. The cover 20 is intended to be assembled with a structural support in order to form a protective casing for a computer. The printed circuit board 13 has an orifice 40 through which a self-tapping screw 41 passes. In one alternative, the printed circuit board 23 has a plurality of orifices 40, through which a plurality of self-tapping screws 41 pass, respectively. Furthermore, the cover 20 comprises a deformation 42 that protrudes with respect to the first face 21. Preferably, the deformation 42 is obtained by stamping. The method for assembling the printed circuit board 23 and the cover 20 comprises a first step of positioning the printed circuit board 23 on the cover 20, then a second step of inserting the self-tapping screw 41 into the orifice 40, then a third step of tightening the self-tapping screw 41. Thus, the printed circuit board 23 is assembled with the cover 20. The deformation 42 comprises an opening 42a, a shaft 42b, which has a length 142, and a base 42c. Preferably, the base 42c is rounded. In one alternative, the base 42c is flat. The self-tapping screw 41 has an under-head length L41. The length 142 of the shaft 42b is shorter than the length L41 of the self-tapping screw 41. The self-tapping screw 41 has a head 41a comprising a hexagonal socket 41b. As an alternative, the head 41a has a cruciform socket or a slot.

According to the invention, the metal element of a protective casing of a computer, which is described in the form of a structural support 10 in the first embodiment and of a cover 20 in the second embodiment, may comprise a plurality of deformations that respectively receive a plurality of self-tapping screws, when necessary. For example, a protective casing of large dimensions requires a plurality of deformations and self-tapping screws. Mechanical integrity requirements may also require multiple deformations and self-tapping screws.

The invention has the advantage of being straightforward to implement and inexpensive. Specifically, the operation of assembling the printed circuit board onto one of the elements of a protective casing for a computer by screwing does not require complex means of production and can be easily automated. The deformations produced do not generate chips, thus preventing the risk of short circuits. Moreover, the invention makes it possible to achieve excellent sealing with respect to the outside.

1. A metal element, of a protective casing of a computer for a motor vehicle, which metal element has a first face, which is intended to be oriented toward the exterior of said protective casing, and a second face, which is intended to be oriented toward the interior of said protective casing, said element comprising a printed circuit board, wherein said element comprises at least one deformation that protrudes with respect to said first face, said printed circuit board being attached to said second face by way of a self-tapping screw implanted in said deformation.

2. The element as claimed in claim 1, wherein said deformation comprises a base, said base being rounded or flat.

3. The element as claimed in claim 1, wherein said deformation comprises an opening, said element comprising a planar surface arranged around said opening.

4. The element as claimed in claim 1, wherein said self-tapping screw has a hexagonal socket.

5. The element as claimed in claim 1, wherein said element is made from an alloy of aluminum or a steel, and said self-tapping screw is made from a steel.

6. The element as claimed in claim 1, wherein said self-tapping screw has an under-head length and said deformation has a shaft that has a length that is shorter than the under-head length of said self-tapping screw.

7. The element as claimed in claim 1, wherein said element comprises at least three deformations, each comprising a self-tapping screw.

8. A protective computer casing for a motor vehicle comprising at least one element as claimed in claim 1.

9. A method for assembling a metal element of a protective casing of a computer for a motor vehicle, which metal element has a first face, which is intended to be oriented toward the exterior of said protective casing, and a second face, which is intended to be oriented toward the interior of said protective casing, said element comprising a printed circuit board, said method comprising:
a step of producing a deformation in said element that protrudes with respect to said first face;
a step of positioning said printed circuit board on said second face;
a step of screwing a self-tapping screw into said deformation in order to assemble said printed circuit board with said element.

10. The method as claimed in claim 9, wherein the step of producing said deformation is achieved by stamping.

11. The element of claim 5, wherein the element comprises stainless steel, and the self-tapping screw comprises stainless steel.

12. The element as claimed in claim 2, wherein said deformation comprises an opening, said element comprising a planar surface arranged around said opening.

13. The element as claimed in claim 2, wherein said self-tapping screw has a hexagonal socket.

14. The element as claimed in claim 3, wherein said self-tapping screw has a hexagonal socket.

15. The element as claimed in claim 2, wherein said element is made from an alloy of aluminum or a steel, and said self-tapping screw is made from a steel.

16. The element as claimed in claim 3, wherein said element is made from an alloy of aluminum or a steel, and said self-tapping screw is made from a steel.

17. The element as claimed in claim 4, wherein said element is made from an alloy of aluminum or a steel, and said self-tapping screw is made from a steel.

18. The element as claimed in claim 2, wherein said self-tapping screw has an under-head length and said deformation has a shaft that has a length that is shorter than the under-head length of said self-tapping screw.

19. The element as claimed in claim 3, wherein said self-tapping screw has an under-head length and said deformation has a shaft that has a length that is shorter than the under-head length of said self-tapping screw.

20. The element as claimed in claim 4, wherein said self-tapping screw has an under-head length and said deformation has a shaft that has a length that is shorter than the under-head length of said self-tapping screw.
